(19) United States
(12) Patent Application Publication
(10) Pub. No.: US 2026/0122806 A1
(43) Pub. Date: Apr. 30, 2026

(54) FLEXIBLE DISPLAY PANEL SUPPORT APPARATUS AND DISPLAY APPARATUS

(71) Applicants: Wuhan Tianma Microelectrorics Co., Ltd. Shanghai Branch, Shanghai (CN); Wuhan Tianma Microelectronics Co., Ltd., Wuhan (CN)

(72) Inventors: Tangliang ZHAO, Shanghai (CN); Yanhua Liu, Shanghai (CN)

(73) Assignees: Wuhan Tianma Microelectronics Co., Ltd. Shanghai Branch, Shanghai (CN); Wuhan Tianma Microelectronics Co., Ltd., Wuhan (CN)

(21) Appl. No.: 19/169,032

(22) Filed: Apr. 3, 2025

(30) Foreign Application Priority Data
Oct. 31, 2024 (CN) 202411547662.0

(51) Int. Cl. H05K 5/02

(52) U.S. Cl. CPC H05K 5/0226

(57) ABSTRACT

The present application relates to a flexible display panel support apparatus and a display apparatus. The flexible display panel support apparatus comprises a support mechanism and a foldable housing. The housing comprises a first portion, a second portion, and a third portion. The second portion and the third portion are disposed at two opposite sides of the first portion respectively. The second portion and the third portion may rotate relative to the first portion in order to fold or unfold the housing. The support mechanism is disposed at an internal folding side of the housing; the support mechanism comprises a support assembly and a drive assembly that is connected to the support assembly; and the drive assembly is configured to drive the support assembly to switch to the support state, or the drive assembly is configured to drive the support assembly to switch to the nonsupport state.

### CROSS REFERENCE TO RELATED APPLICATION

The present application claims priority to Chinese Patent Application No. 202411547662.0 filed on Oct. 31, 2024, which is incorporated herein by reference in its entirety.

### TECHNICAL FIELD

The present application relates to the field of display technology, and in particular to a flexible display panel support apparatus and a display apparatus.

### BACKGROUND

With the development of foldable screen technology, foldable phones have become a trending technology. OLED display screens have been widely used in foldable phones because of features of flexibility and foldability. However, a problem in which a screen body of a bent area is sank may appear on a regular flexible display screen with an increase of folding times, thereby influencing not only appearance but also display effect.

### SUMMARY

In a first aspect, the present application provides a flexible display panel support apparatus and the flexible display panel support apparatus comprises a support mechanism and a foldable housing. The housing comprises a first portion, a second portion, and a third portion, the second portion and the third portion are disposed at two opposite sides of the first portion respectively, and the second portion and the third portion can rotate relative to the first portion to fold or unfold the housing.

The support mechanism is disposed at an internal folding side of the housing; the support mechanism comprises a support assembly and a drive assembly that is connected to the support assembly; an orthographic projection of the support assembly on the housing is within the first portion; and the drive assembly is configured to drive the support assembly to switch to a support state in response to the unfolding motion of the housing, or the drive assembly is configured to drive the support assembly to switch to a nonsupport state in response to the folding motion of the housing.

The flexible display panel support apparatus provided in embodiments of the present application is provided with the support mechanism disposed at an internal folding side of the foldable housing. The support mechanism comprises a support assembly and a drive assembly. When the housing is unfolded, the drive assembly is configured to drive the support assembly to switch to the support state in response to the unfolding motion of the housing, thereby supporting the bent portion of the flexible display panel and preventing the bent portion deforming. When the housing is folded, the drive assembly is configured to drive the support assembly to switch to the nonsupport state in response to the folding motion of the housing, thereby facilitating a deformation of the bent portion, preventing the support assembly from interfering with the deformation of the bent portion to damage the bent portion. In summary, the flexible display panel support apparatus provided in the present application can avoid sinking the bent portion, improve the display effect, reduce the interference with the deformation of the bent portion, and increase service life of the flexible display panel.

In a second aspect, embodiments of the present application provide a display apparatus comprising a flexible display panel and the above flexible display panel support apparatus, the flexible display panel is disposed at a side of the support mechanism away from the housing, the flexible display panel comprises a bent portion, and the support portion is disposed between the bent portion and the first portion.

The display apparatus provided in embodiments of the present application is provided with the support mechanism disposed at the internal folding side of the foldable housing and the support mechanism comprises a support assembly and a drive assembly. When the housing is unfolded, the drive assembly is configured to drive the support assembly to switch to the support state in response to the unfolding motion of the housing. When the housing is folded, the drive assembly is configured to drive the support assembly to switch to the nonsupport state in response to the folding motion of the housing.

### BRIEF DESCRIPTION OF THE DRAWINGS

In order to more clearly illustrate the technical solutions of embodiments of the present application, the drawings to be used in the embodiments of the present application will be briefly introduced below. It is obvious that the drawings described below are merely some embodiments of the present application, and for those of ordinary skill in the art, other drawings can be obtained based on these drawings without inventive effort.

FIG. 1 is a schematic structural view of a flexible display apparatus in the related art.

FIG. 2 is a schematic structural view of a flexible display panel support apparatus according to an embodiment of the present application.

FIG. 3 is a schematic structural view of a fixed shaft and a support piece of the flexible display panel support apparatus shown in FIG. 2.

FIG. 4 is a schematic structural view of a support assembly of the flexible display panel support apparatus shown in FIG. 2.

FIG. 5 is a schematic view of a first outer diameter and a second outer diameter of the flexible display panel support apparatus shown in FIG. 2.

FIG. 6 is a schematic view of lengths of different states of a draw cord in the flexible display panel support apparatus shown in FIG. 2.

FIG. 7 is a schematic structural view of an elastic piece of the flexible display panel support apparatus shown in FIG. 2.

FIG. 8 is a schematic planar view of the flexible display panel support apparatus shown in FIG. 2.

FIG. 9 is a schematic cross-sectional structural view of a display apparatus provided in an embodiment of the present application.

FIG. 10 is a schematic cross-sectional structural view of another display apparatus provided in an embodiment of the present application.

### REFERENCE SIGNS

Flexible screen 1′; flat portion 11′; curved portion 12′; casing 2′;
Display apparatus 10; flexible display panel support apparatus 1; housing 11; first portion 111; second portion 112; third portion 113; rotary shaft 114; support mechanism 12; support assembly 121; fixed shaft 1211; support piece 1212; shaft body 12121; long rod body 12122; short rod body 12123; intermediate rod body 12124; pulley 12125; reinforcement piece 1213; drive assembly 122; draw cord 1221; guide wheel 1222; elastic piece 1223; first end 12231; second end 12232; elastic film layer 13; flexible display panel 2; bent portion 21; first straight portion 22; second straight portion 23; frame 3.

### DETAILED DESCRIPTION

For the convenience of understanding the present application, a more comprehensive description of the present application is provided below with reference to the relevant accompanying drawings. Preferred embodiments of the present application are shown in the accompanying drawings. However, the present application can be implemented in many different forms, and is not limited to the embodiments described herein. On the contrary, these embodiments are provided for a more thorough and comprehensive understanding of the disclosure of the present application.

Unless otherwise defined, all technical and scientific terms used herein have the same meaning as commonly understood by a person skilled in the art to which the present application belongs. The terms used in the description of the present application are only for the purpose of describing specific embodiments, but are not intended to limit the present application. The term “and/or” used herein includes any and all combinations of one or more relevant listed items.

When describing positional relationships, unless otherwise specified, when one element such as a layer, film, or substrate is referred to as “on” the other element, the element may be directly on the other element or there may be an intermediate element between them. Further, when one layer is referred to as “below” the other layer, the layer may be directly below or there may be one or more light-emission unit between them. It can also be understood that when one layer is referred to as “between” two layers, the layer may be the only layer between the two layers, or there may be one or more light-emission unit between them.

When the terms “include”, “have”, and “comprise” described herein are used, another component may be added unless explicit limiting terms such as “only” and “composed of” are used. Unless mentioned to the contrary, the terms in singular forms may include plural forms and cannot be understood as having one.

It should be understood that although the terms “first”, “second”, etc. may be used herein to describe various elements, these elements should not be limited by these terms. These terms are only used to distinguish one element from another. For example, without departing from the scope of the present application, the first element may be referred to as the second element, and similarly, the second element may be referred to as the first element.

It should also be understood that when an element is interpreted, although not explicitly described, the element is interpreted as including an error range, which should be within a specific acceptable deviation range determined by those skilled in the art. For example, “about”, “approximately”, or “essentially” may mean within one or more standard deviations, which are not limited here.

Furthermore, in the description, the phrase “planar distribution view” refers to an accompanying drawing when viewing a target portion from above, and the phrase “cross-sectional view” refers to an accompanying drawing when viewing a cross-section taken by vertically cutting a target portion from a side surface.

In addition, the accompanying drawings are not drawn to a 1:1 scale, and the relative dimensions of each element are only shown as an example in the accompanying drawings, not necessarily drawn to true scale.

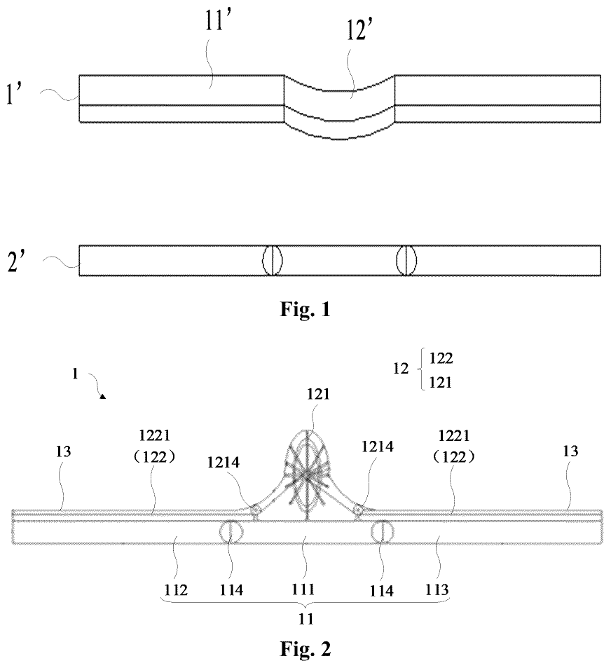

With the development of foldable screen technology, foldable phones have become a trending technology. OLED display screens have been widely used in foldable phones because of features of flexibility and foldability. As shown in FIG. 1, a flexible display apparatus in the related art comprises a flexible screen 1′ and a casing 2′. When folded, the casing 2′ and the flexible screen 1′ are folded toward inside simultaneously; when unfolded, the casing 2′ and the flexible screen 1′ are unfolded toward outside simultaneously. With an increase of folding times, there may be a sinking problem on a bent portion 12′ of the flexible screen 1′, i.e., in an unfolded state, the upper surface of the bent portion 12′ is lower than the upper surface of the flat portion 11′. As such, it not only affects the appearance, but also easily causes poor display of the bent portion 12′, thereby affecting the display effect.

In view of at least one of the above problems, embodiments of the present application provide a flexible display panel and a display apparatus. A support mechanism is disposed at an internal folding side of the foldable housing and comprises a support assembly and a drive assembly. When the housing is unfolded, the drive assembly is configured to drive the support assembly to switch to the support state in response to the unfolding motion of the housing, thereby supporting the bent portion of the flexible display panel and preventing the bent portion from sinking. When the housing is folded, the drive assembly is configured to drive the support assembly to switch to the nonsupport state in response to the folding motion of the housing, thereby facilitating a deformation of the bent portion, preventing the support assembly from interfering the deformation of the bent portion to damage the bent portion. In summary, the present application can avoid the sinking of the bent portion, improve the display effect, reduce the interference with the deformation of the bent portion, and increase service life of the flexible display panel.

In the first aspect, as shown in FIG. 1, embodiments of the present application provide a flexible display panel support apparatus 1 comprising a support mechanism 12 and a foldable housing 11. The housing 11 comprises a first portion 111, a second portion 112, and a third portion 113; the second portion 112 and the third portion 113 are disposed at two opposite sides of the first portion 111 respectively; and the second portion 112 and the third portion 113 can rotate relative to the first portion 111 to fold or unfold the housing 11.

The support mechanism 12 is disposed at an internal folding side of the housing 11 and comprises a support assembly 121 and a drive assembly 122 connected to the support assembly 121; an orthographic projection of the support assembly 121 on the housing 11 is in the first portion 111, that is, at least part of the support assembly 121 is located over the first portion 111. The drive assembly 122 drives the support assembly 121 to switch to a support state in response to the unfolding motion of the housing 11, or the drive assembly 122 drives the support assembly 121 to switch to a nonsupport state in response to the folding motion of the housing 11. It can be understood that the support assembly 121 in the support state is contacted with a bent portion 21 of the flexible display panel 2 and provides a supporting force to support the bent portion 21; the support assembly 121 in the nonsupport state does not provide the supporting force to the bent portion 21. It should be noted that the support assembly 121 in the nonsupport state may be contacted with the bent portion 21, or not.

Here, the orthographic projection of the support assembly 121 on the housing 11 is a projection of the support assembly 121 on the housing 11 in a direction perpendicular to a plane where the housing 11 lies.

When the housing 11 is folded, the housing 11 is folded toward one side and this side is the internal folding side of the housing 11. For example, the housing 11 has an A face and B face disposed opposite to each other, and the A face comprises an A1 face and an A2 face that are located at two sides of a folding area (bent area) respectively. When folded, the housing 11 is folded toward a side where the A face is located and the A1 face and the A2 face are close to each other. As such, the side where the A face is located is the internal folding side, and the side where the B face is located is the external folding side.

The flexible display panel support apparatus 1 provided in embodiments of the present application is provided with the support mechanism 12 disposed at the internal folding side of the foldable housing 11 and the support mechanism 12 comprises the support assembly 121 and the drive assembly 122. When the housing 11 is unfolded, the drive assembly 122 is configured to drive the support assembly 121 to switch to the support state in response to the unfolding motion of the housing 11, thereby supporting the bent portion 21 of the flexible display panel 2 and preventing the bent portion 21 from sinking. When the housing 11 is folded, the drive assembly 122 is configured to drive the support assembly 121 to switch to the nonsupport state in response to the folding motion of the housing 11, thereby facilitating a deformation of the bent portion 21, preventing the support assembly 121 influencing the deformation of the bent portion 21, and damaging the bent portion 21. In summary, the flexible display panel support apparatus 1 provided by the present application can avoid the sinking of the bent portion 21, improve the display effect, reduce the interference with the deformation of the bent portion 21, and increase service life of the flexible display panel 2.

In an embodiment, the first portion 111 and the second portion 112 are rotatablely connected by a rotary shaft 114; the first portion 111 and the third portion 113 are rotatablely connected by the rotary shaft 114.

It should be noted that the drive assembly 122 can be an electric drive mechanism or mechanical drive mechanism relied on an external force and a drive type of the drive assembly 122 is not limited in embodiments of the present application.

In an embodiment, the drive assembly 122 is an electric drive mechanism; the electric drive mechanism is responded to the unfolding motion of the housing 11 to drive the support assembly 121 to switch to the support state; and the electric drive mechanism is responded to the folding motion of the housing 11 to drive the support assembly 121 to switch to the nonsupport state.

Specifically, the electric drive mechanism receives an unfolding signal of the housing 11, outputs power, and drives the support assembly 121 to switch to the support state; the electric drive mechanism receives a folding signal of the housing 11, outputs power, and drives the support assembly 121 to switch to the nonsupport state.

The drive assembly 122 provided with the electric drive mechanism can provide the flexible display panel 2 with a supporting force relatively stable and durable, thereby having a relatively well effect of avoiding the sinking of the bent portion 21.

It should be noted that the electric drive mechanism can be a motor.

Optionally, the flexible display panel support apparatus 1 further comprises a detection assembly and a control chip and the detection assembly is configured to detect a folding information and/or unfolding information of the flexible display panel 2. In an example, the detection assembly is a resistance detection piece; in different states (the folded state and unfolded state) of the flexible display panel 2, the resistance detection piece detects different resistances; and the control chip determines the state of the flexible display panel 2 according to the detected resistance to control the electric drive mechanism work. It can be understood that the control chip herein can be assembled on a chip of the display apparatus 10.

It should be noted that when the drive assembly 122 is a mechanical drive mechanism, an external force is acted on the mechanical drive mechanism to make the mechanical drive mechanism work, and the support assembly 121 is driven to switch between the support state and nonsupport state.

In an embodiment, as shown in FIGS. 2-5, the support assembly 121 comprises a fixed shaft 1211 and a support piece 1212, and the fixed shaft 1211 is fixed at a folding side of the first portion 111. That is, the fixed shaft 1211 is fixed at a side of the first portion 111 close to a folding direction. The support piece 1212 is rotatablely disposed on the fixed shaft 1211. In an example, the support piece 1212 is rotatablely sleeved on the fixed shaft 1211.

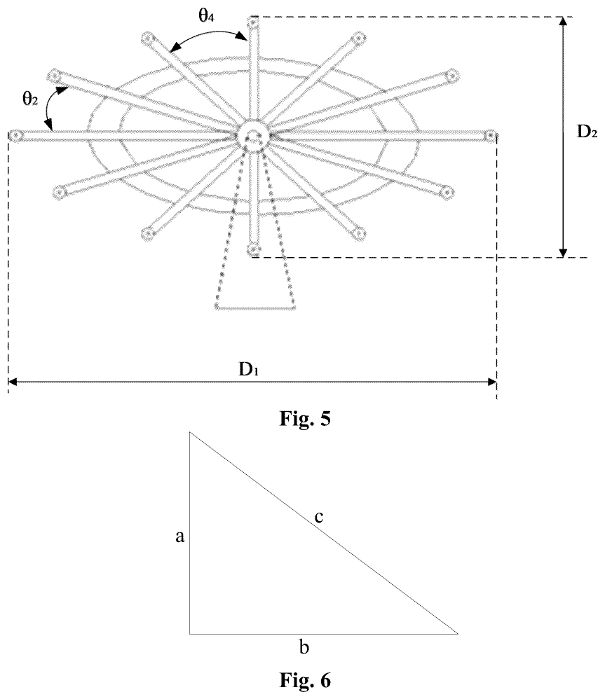

As shown in FIG. 5, in a rotary periphery of the support piece 1212, the support piece 1212 is provided with a first outer diameter D₁ and a second outer diameter D₂ and the first outer diameter D₁ is larger than the second outer diameter D₂; when the support assembly 121 is in the support state, a direction in which the first outer diameter D₁ is located is parallel to a thickness direction of the housing 11, that is, the direction in which the first outer diameter D₁ is located is perpendicular to the plane where the housing lies; and when the support assembly 121 is in the nonsupport state, a direction in which the second outer diameter D₂ is located is parallel to a thickness direction of the housing 11, that is, the direction in which the second outer diameter D₂ is located is perpendicular to the plane where the housing lies.

Here, the thickness direction of the housing 11 can be referred as a direction perpendicular to a plane where the housing 11 is located. In FIG. 2, a thickness direction of the housing 11 is a vertical direction. It should be noted that the term “parallel” in embodiments of the present application can be absolutely parallel or approximately parallel and the term “perpendicular” can be absolutely perpendicular or approximately perpendicular.

The above arrangement can make the structure of the support assembly 121 relatively simple, thereby not only reducing the manufacturing cost but also decreasing the assembly difficulty.

In an embodiment, a flange (not shown) is disposed at the side of the first portion 111 close to the folding direction and the fixed shaft 1211 is fixed on the flange.

In an embodiment, a circle center (or a center point) of the first outer diameter coincides with a shaft center of the fixed shaft 1211 and a circle center (or a center point) of the second outer diameter coincides with the shaft center of the fixed shaft 1211.

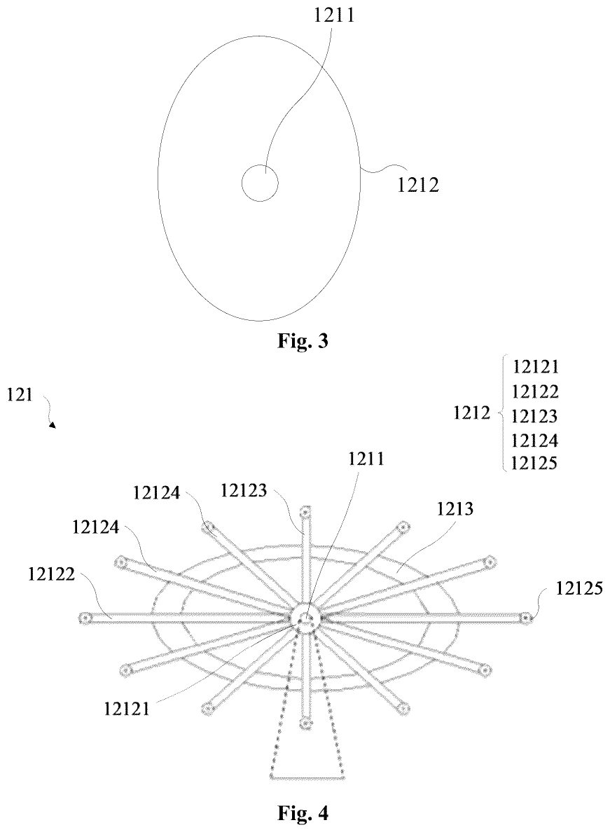

In an embodiment, as shown in FIG. 3, the support piece 1212 is an ellipse-shaped disc. The first outer diameter is a long shaft of the ellipse-shaped disc and the second outer diameter is a short shaft of the ellipse-shaped disc. In the support state, the long shaft of the ellipse-shaped disc is perpendicular to a direction of the plane where the housing 11 is located and the short shaft of the ellipse-shaped disc is parallel to the direction of the plane where the housing 11 is located. In the nonsupport state, the short shaft of the ellipse-shaped disc is perpendicular to the direction of the plane where the housing 11 is located and the long shaft of the ellipse-shaped disc is parallel to the direction of the plane where the housing 11 is located.

The support piece 1212 provided with the ellipse-shaped disc allows to a relatively strong structural strength, which is beneficial to increasing service life.

In an embodiment, as shown in FIG. 4, the support piece 1212 comprises a shaft body 12121, two long rod bodies 12122, and two short rod bodies 12123. The shaft body 12121 is rotatablely sleeved on the fixed shaft 1211, i.e., the shaft body 12121 can rotate relative to the fixed shaft 1211. Two long rod bodies 12122 are disposed at two opposite sides of the shaft body 12121. Specifically, straight lines where shaft center lines of two long rod bodies 12122 are located coincide or approximately coincide with each other. Two short rod bodies 12123 are disposed at two opposite sides of the shaft body 12121. Specifically, straight lines where shaft center lines of two short rod bodies 12123 are located coincide or approximately coincide with each other. The length of the long rod body 12122 is larger than the length of the short rod body 12123. It can be understood that the first outer diameter is a distance between respective ends of two long rod bodies 12122 that are away from each other, and the second outer diameter is a distance between respective ends of two short rod bodies 12123 that are away from each other.

In an embodiment, two long rod bodies 12122 and two short rod bodies 12123 are disposed alternately and evenly along a circumferential direction (i.e., a cyclic direction) of the shaft body 12121. Specifically, along a clockwise (or anticlockwise) direction of the shaft body 12121, the rod bodies are arranged sequentially in the following order: long rod body 12122, short rod body 12123, long rod body 12122, short rod body 12123. Under a condition that the long rod body 12122 and the short rod body 12123 are adjacent, an angle between shaft center lines of the long rod body 12122 and the short rod body 12123 are 90 degrees.

The above arrangement allows a circumferential distribution of the long rod bodies 12122 and the short rod bodies 12123 on the shaft body 12121 to be relatively even, thereby allowing the support piece 1212 to be relatively symmetric in structure and facilitating the rotation of the support piece 1212. It can be understood that when the support assembly 121 switches from the nonsupport state to the support state, the shaft body 12121 of the support piece 1212 rotates 90 degrees in clockwise or anticlockwise; and when the support assembly 121 switches from the support state to the nonsupport state, the shaft body 12121 of the support piece 1212 rotates 90 degrees in clockwise or anticlockwise.

In an embodiment, the support piece 1212 further comprises an intermediate rod body 12124. The length of the intermediate rod body 12124 is smaller than the length of the long rod body 12122 and the length of the intermediate rod body 12124 is larger than the length of the long rod body 12123. Along the circumferential direction of the shaft body 12121, at least one intermediate rod body 12124 are disposed between the long rod body 12122 and the short rod body 12123.

As such, in the process of switching from the support state to the nonsupport state, after the long rod body 12122 is moved out of contact with the bent portion 21 of the flexible display panel 2, the intermediate rod body 12124 can be contact with the bent portion 21 of the flexible display panel 2 to support the bent portion 21; in the process of switching from the nonsupport state to the support state, the intermediate rod body 12124 is firstly contact with the bent portion 21 of the flexible display panel 2, the flexible display panel 2 is gradually unfolded, and the long rod body 12122 is contacted with the bent portion 21 of the flexible display panel 2 after the flexible display panel 2 is completely unfolded. In this way, in the process of switching the state, the intermediate rod body 12124 may play a transition role to prevent a large sudden change in the supporting force applied to the bent portion 21 of the flexible display panel 2, which is beneficial to increasing the service life of the flexible display panel 2.

In an embodiment, a plurality of intermediate rod bodies 12124 are disposed between the long rod body 12122 and the short rod body 12123, wherein for any two adjacent of the intermediate rod bodies 12124, the length of the intermediate rod body 12124 relatively close to the long rod body 12122 is larger than the length of the intermediate rod body 12124 relatively away from the long rod body 12122. As shown in FIG. 4, two intermediate rod bodies 12124 are disposed between the long rod body 12122 and the short rod body 12123 adjacent to each other; and for two intermediate rod bodies 12124, the length of the intermediate rod body 12124 closest to the long rod body 12122 is larger than a length of another intermediate rod body 12124. That is, lengths of rod bodies from the long rod body 12122 to the short rod body 12123 are gradually decreased in the anticlockwise direction.

Here, a state between the support state and the nonsupport state is defined as an intermediate state. The above arrangement can provide a relatively good support to the bent portion 21 of the flexible display panel 2 in the intermediate state; a support condition of the support assembly 121 in the intermediate state matches a deformation situation of the bent portion 21; and in this way, a support force applied to the bent portion 21 of the flexible display panel 2 can be transited smoothly, which is beneficial to increasing the service life of the flexible display panel 2.

It can be understood that one, three, four or more intermediate rod body 12124 can be disposed between the long rod body 12122 and the short rod body 12123 adjacent to each other and the number of the intermediate rod body 12124 is not limited in embodiments of the present application.

In an embodiment, the length of the long rod body 12122 or the intermediate rod body 12124 satisfies the following relationship:

$${L}_{N} = \sqrt{N} \times {L}_{1}$$

in which L₁ is the length of the short rod body 12123, N is a anticlockwise sequence number of the long rod body 12122 or the intermediate rod body 12124, and L_{N} is the length of the long rod body 12122 or the intermediate rod body 12124.

Specifically, in an example of FIG. 5, a sequence number of the short rob body 12123 is 1 and the length thereof is L₁; a sequence number of the first intermediate rod body 12124 is 2 and the length thereof is \sqrt{2}L₁; a sequence number of the second intermediate rod body 12124 is 3 and the length thereof is \sqrt{3}L₁; and a sequence number of the long rod body 12122 is 4 and the length thereof is 2L₁.

As such, the lengths of the long rod body 12122, the intermediate rod body 12124, and the short rod body 12123 can be reasonably set, so that lengths of the rod bodies from the long rod body 12122 to the short rod body 12123 can be transited reasonably, and therefore the support condition of the support assembly 121 in the intermediate state matches the deformation condition of the bent portion 21. In this way, the supporting force applied to the bent portion 21 of the flexible display panel 2 can be transited smoothly, which is beneficial to increasing the service life of the flexible display panel.

In an embodiment, for the long rod body 12122, the intermediate rod body 12124, and the short rod body 12123, an angle between any two adjacent rod bodies satisfies the following relationship:

$${θ}_{n} = ( 1 - \frac{\sqrt{n}}{n} ) {θ}_{2}$$

in which θ₂ is an angle between the long rod body 12122 and the intermediate rod body 12124 adjacent to the long rod body 12122; θₙ is an angle between two adjacent rod bodies; n is a clockwise sequence number of the body rod away from the long rod body 12122 in two adjacent rod bodies.

Specifically, in an example of FIG. 5, in the clockwise direction, a sequence number of the long rod body 12122 is 1, a sequence number of the first intermediate rod body 12124 is 2, a sequence number of the second intermediate rod body 12124 is 3, and a sequence number of the short rod body 12123 is 4. An angle between the first intermediate rod body 12124 and the second intermediate rod body 12124 is θ₃ and an angle between the short rod body 12123 and the second intermediate rod body 12124 is θ₄.

As such, the angles among the long rod body 12122, the intermediate rod body 12124, the short rod body 12123 can be arranged reasonably, so that the angle between two adjacent rod bodies matches the length of two adjacent rod bodies, and therefore the supporting condition of the support assembly 121 in the intermediate state matches the deformation condition of the bent portion 21. In this way, the supporting force applied to the bent portion 21 of the flexible display panel 2 can be transited smoothly, which is beneficial to increasing the service life of the flexible display panel 2.

In an embodiment, with reference to FIG. 4, the support assembly 121 further comprises a reinforcement piece 1213. For the long rod body 12122, the intermediate rod body 12124, and the short rod body 12123, the reinforcement piece 1213 is disposed between two adjacent rod bodies. The reinforcement piece 1213 can connects two adjacent rod bodies and improve assembly stability of the rod body, thereby improving the structural strength and assembly stability of the support piece 1212.

In an embodiment, the support assembly 121 comprises a plurality of reinforcement pieces 1213, the plurality of reinforcement pieces 1213 are evenly arranged around the shaft body 12121, one reinforcement piece 1213 are disposed between any two adjacent rod bodies, the shape of each reinforcement piece 1213 is similar to an arc shape, and all reinforcement pieces 1213 are assembled to form a structure similar to an ellipse shape.

In an embodiment, referring to FIG. 4, the support piece 1212 further comprises pulleys 12125. The pulleys 12125 are disposed at an end portion of the long rod body 12122 away from the shaft body 12121, an end portion of the short rod body 12123 away from the shaft body 12121, and an end portion of the intermediate rod body 12124 away from the shaft body 12121. The pulleys 12125 can reduce the friction force between the rod body and the flexible display panel 2 and avoid damage of the flexible display panel resulting from directly contact between the rod body and the flexible display panel 2.

As shown in FIG. 5, it should be understood that when the support piece 1212 comprises the pulleys 12125, the first outer diameter D₁ is equal to a maximal distance between sides of two pulleys 12125 away from each other on the long rod bodies 12122, and the second outer diameter D₂ is equal to a maximal distance between sides of two pulleys 12125 away from each other on the short rod bodies 12123.

In an embodiment, referring to FIG. 2, the drive assembly 122 comprises a draw cord 1221, one end of the draw cord 1221 is connected to the second portion 112 or the third portion 113, another end of the draw cord 1221 is connected to the support assembly 121, and the draw cord 1221 can respond to the unfolding motion of the housing 11 to drive the support assembly 121 to switch to the support state. As such, when the housing 11 is unfolded, a draw force unfolding the housing is acted on the draw cord 1221, the draw cord 1221 draws the support assembly 121 to rotate, and the support assembly 121 switches from the nonsupport state to the support state. The above arrangement can decrease the structural complexity of the support mechanism 12, thereby reducing the manufacturing cost and assembly difficulty.

Referring to FIG. 6, it should be noted that when the support assembly 121 is in the support state, the length of the draw cord 1221 is a+b; and when the support assembly 121 is in the nonsupport state, the length of the draw cord 1221 is c. In the process of switching from the nonsupport state to the support state, the draw cord 1221 is drew and lengthened, and the draw cord 1221 exerts an force on the support assembly 121, thereby driving the support assembly 121 to rotate.

In an embodiment, one end of the draw cord 1221 close to the support assembly 121 is connected to the rod body (e.g., the long rod body 12122) of the support piece 1212.

In an embodiment, the drive assembly 122 comprises two draw cords 1221, an end of one of two draw cords 1221 is connected to the second portion 112, and another end of such draw cord 1221 is connected to the support piece 1212; an end of the other draw cord 1221 is connected to the third portion 113, and another end of the other draw cord 1221 is connected to the support piece 121.

In an embodiment, referring to FIG. 2, the drive assembly 122 further comprises a guide wheel 1222, the guide wheel is disposed on the first portion 111, and the draw cord 1221 is tensely disposed on the guide wheel 1222. The guide wheel 1222 can guide the draw cord 1221 and facilitate that the draw cord 1221 draws the support assembly 1212, thereby driving the support piece 1212 to rotate. It can be understood that a number of the guide wheel 1222 can be multiple, the number of the guide wheel 1222 is not limited in embodiments of the present application.

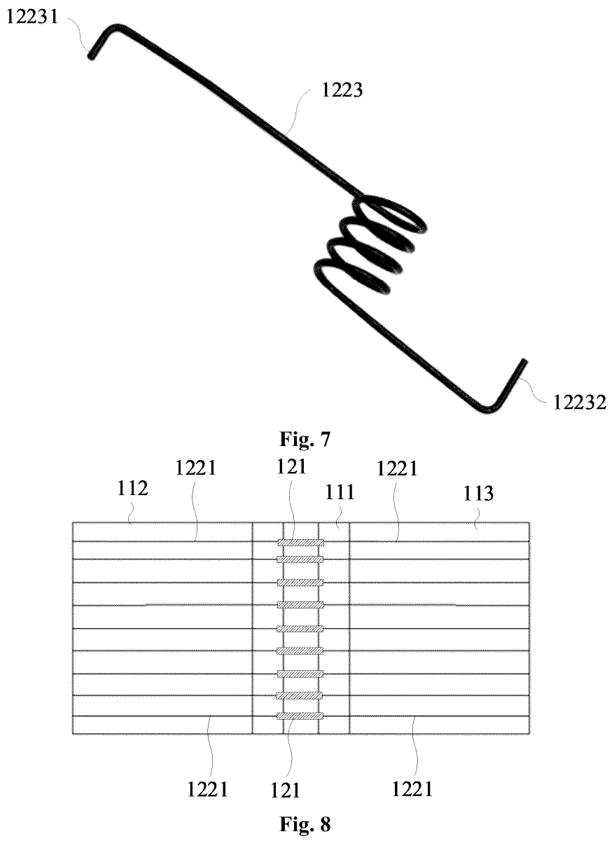

In an embodiment, referring to FIG. 7, the drive assembly 122 comprises an elastic piece 1223 and responds to the folding motion of the housing 11, thereby driving the support assembly 121 to switch to the nonsupport state. It can be understood that in a process of switching from the unfolded state to the folded state, the draw cord 1221 is in a relax state; the support assembly 121 cannot autonomously switch the state; by disposing the elastic piece 1223, the resiliency of the elastic piece 1223 can reset the support assembly 121 from the support state to the nonsupport state, which facilitates that the support assembly 121 supports the bent portion 21 of the flexible display panel 2 in the next unfolding.

In an embodiment, the elastic piece 1223 is a torsion spring, one end of the torsion spring is connected to the support assembly 121, and another end of the torsion spring is connected to the first portion 111. As shown in FIG. 7, that is, a first end 12231 of the torsion spring is connected to the support assembly 121 and a second end 12232 of the torsion spring is connected to the first portion 111. It should be noted that when the support assembly 121 is in the support state, the torsion spring is in a compressed state; and when the support assembly 121 is in the nonsupport state, the torsion spring is in an original state.

As such, the elastic piece 1223 can have a simple structure, the structural difficulty of the support mechanism 12 can be decreased, and the manufacturing cost and the assembly difficulty can be reduced.

In an embodiment, referring to FIG. 2, the flexible display panel support apparatus 1 further comprises an elastic film layer 13; and the elastic film layer 13 is wrapped on a side of the support mechanism 12 away from the housing 11. On the one hand, the elastic film layer 13 can warp the support mechanism 12 to enclose and protect the support mechanism 12; and on the other hand, the elastic film layer 13 may perform adaptive deformation and the motion of the support assembly 121 is not blocked.

In an example, the material of the elastic film layer 13 can include rubber.

In an example, referring to FIG. 8, the flexible display panel support apparatus 1 comprises a plurality of support mechanism 12; and the plurality of support mechanism 12 are arranged at intervals along a width direction of the housing 11 (parallel to the plane where the housing 11 is located). As such, the support assembly 121 may have a better support effect of the flexible display panel 2, which is beneficial to reducing the sinking problem of the bent portion 21 of the flexible display panel 2.

In a second aspect, as shown in FIG. 9, embodiments of the present application provide a display apparatus 10, which may be a notebook computer, a mobile phone, a wireless device, a personal digital assistant (PDA), a handhold or portable computer, GPS receiver/navigator, a camera, a MP4 video player, a camcorder, a game controller, a watch, a clock, a calculator, a television monitor, a tablet display, a computer monitor, an automotive display (e.g., an odometer display), a navigation equipment, a cockpit control and/or display, a display of a camera view (e.g., a display of a rear view camera in a vehicle), an electronic photograph, an electronic billboard or sign, a projector, and a packaging.

Specifically, the display apparatus 10 comprises the flexible display panel 2 and the above flexible display panel support apparatus 1; the flexible display panel 2 is disposed at one side of the support mechanism 12 away from the housing 11; the flexible display panel 2 comprises the bent portion 21; and the support assembly 121 is disposed between the bent portion 21 and the first portion 111. Furthermore, the flexible display panel 2 further comprises a first straight portion 22 and a second straight portion 23 and the bent portion 21 is connected to the first straight portion 22 and the second straight portion 23.

The display apparatus 10 provided in embodiments of the present application is provided with the support mechanism 12 disposed at the internal folding side of the foldable housing 11; and the support mechanism 12 comprises the support assembly 121 and the drive assembly 122. When the housing 11 is unfolded, the drive assembly 122 is configured to drive the support assembly 121 to switch to the support state in response to the unfolding motion of the housing 11, thereby supporting the bent portion 21 of the flexible display panel 2 and preventing the bent portion 21 from sinking. When the housing 11 is folded, the drive assembly 122 is configured to drive the support assembly 121 to switch to the nonsupport state in response to the folding motion of the housing 11, thereby facilitating deformation of the bent portion 21, preventing the support assembly 121 from interfering with the deformation of the bent portion 21 to damage the bent portion 21. In summary, the display apparatus 10 provided in the present application can avoid sinking of the bent portion 21, improve the display effect, reduce the interference with the deformation of the bent portion 21, and increase service life of the flexible display panel 2.

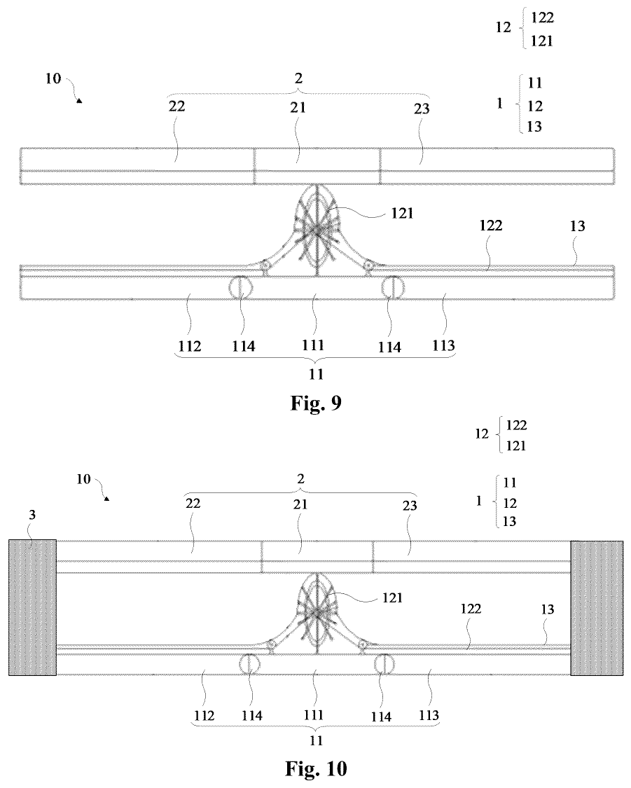

In an embodiment, as shown in FIG. 10, the display apparatus 10 further comprises a frame 3 surrounding the housing 11. It should be noted that the material of the frame 3 may be metal.

The technical features of the above embodiments can be combined in any way, and in order to make the description clear, not all the possible combinations of the technical features in the above embodiments are described. However, as long as there is no contradiction among the combinations of these technical features, they should be considered as the scope that the specification recites.

Embodiments described above represent only a few implementations of the present application and description thereof is relatively specific and detailed, but are not to be construed as limiting the scope of the present application. It should be noted that a person skilled in the art could also make several changes and modifications without departing from the concept of the present application, which falls within the protection scope of this application. Therefore, the protection scope of the present application should be subject to the appended claims.

What is claimed is:

1. A flexible display panel support apparatus, comprising:
a foldable housing comprising a first portion, a second portion, and a third portion, wherein the second portion and the third portion are connected to two opposite sides of the first portion respectively; and
a support mechanism disposed at an internal folding side of the housing and comprising a support assembly and a drive assembly that is connected to the support assembly, an orthographic projection of the support assembly on the housing being located within the first portion, wherein the drive assembly is configured to drive the support assembly to switch to a support state in response to an unfolding motion of the housing or drive the support assembly to switch to a nonsupport state in response to a folding motion of the housing.

2. The flexible display panel support apparatus according to claim 1, wherein the support assembly comprises:
a fixed shaft fixed at a folding side of the first portion; and
a support piece rotatablely disposed on the fixed shaft, wherein
in a rotary periphery of the support piece, and the support piece is provided with a first outer diameter and a second outer diameter, the first outer diameter being larger than the second outer diameter;
under a condition that the support assembly is in the support state, a direction in which the first outer diameter is located is parallel to a thickness direction of the housing; and under a condition that the support assembly is in the nonsupport state, a direction in which the second outer diameter is located is parallel to the thickness direction of the housing.

3. The flexible display panel support apparatus according to claim 2, wherein the support piece comprises:
a shaft body rotatablely sleeved on the fixed shaft;
two long rod bodies disposed on two opposite sides of the shaft body respectively; and
two short rod bodies disposed on the two opposite sides of the shaft body respectively, a length of each of the two long rod bodies being larger than a length of each of the two short rod bodies.

4. The flexible display panel support apparatus according to claim 3, wherein the two long rod bodies and the two short rod bodies are disposed alternately and evenly along a circumferential direction of the shaft body.

5. The flexible display panel support apparatus according to claim 4, wherein the support piece further comprises at least one intermediate rod body, which is disposed between the long rod body and the short rod body along the circumferential direction of the shaft body.

6. The flexible display panel support apparatus according to claim 5, wherein a plurality of the intermediate rod bodies are disposed between the long rod body and the short rod body; and for adjacent two of the plurality of the intermediate rod bodies, a length of the intermediate rod body relatively close to the long rod body is larger than a length of the intermediate rod body relatively away from the long rod body.

7. The flexible display panel support apparatus according to claim 6, wherein the length of the long rod body or the intermediate rod body satisfies the following relationship:
$${L}_{N} = \sqrt{N} \times {L}_{1}$$
in which L₁ is the length of the short rod body; N is an anticlockwise sequence number of the long rod body or the intermediate rod body; and L_{N} is the length of the long rod body or the intermediate rod body.

8. The flexible display panel support apparatus according to claim 6, an included angle between any two adjacent rod bodies in the long rod body, the intermediate rod bodies, and the short rod body satisfies the following relationship:
$${θ}_{n} = ( 1 - \frac{\sqrt{n}}{n} ) {θ}_{2}$$
in which θ₂ is an included angle between the long rod body and the intermediate rod body adjacent to the long rod body; θₙ is an included angle between the two adjacent rod bodies; and
n is clockwise sequence number of one of the two adjacent rod bodies that is relatively away from the long rod body.

9. The flexible display panel support apparatus according to claim 5, wherein the support assembly further comprises a reinforcement piece disposed between any two adjacent rod bodies of the two long rod bodies, the at least one intermediate rod body, and the two short rod bodies.

10. The flexible display panel support apparatus according to claim 5, wherein the support piece further comprises pulleys disposed at an end portion of each of the two long rod bodies away from the shaft, an end portion of each of the two short rod bodies away from the shaft, and an end portion of each of the at least one intermediate rod body away from the shaft, respectively.

11. The flexible display panel support apparatus according to claim 1, wherein the drive assembly comprises a draw cord; one end of the draw cord is connected to the second portion or the third portion; the other end of the draw cord is connected to the support assembly; and the draw cord is configured to drive the support assembly to switch to the support state in response to the unfolding motion of the housing.

12. The flexible display panel support apparatus according to claim 11, wherein the drive assembly further comprises a guide wheel disposed on the first portion, and the draw cord is tensely disposed on the guide wheel.

13. The flexible display panel support apparatus according to claim 1, wherein the drive assembly comprises an elastic piece and is configured to drive the support assembly to switch to the nonsupport state in response to the folding motion of the housing.

14. The flexible display panel support apparatus according to claim 13, wherein the elastic piece is a torsion spring, one end of the torsion spring is connected to the support assembly, and the other end of the torsion spring is connected to the first portion.

15. The flexible display panel support apparatus according to claim 1 further comprising an elastic film layer, wherein the elastic film layer is wrapped on a side of the support mechanism away from the housing.

16. A display apparatus, comprising:
a flexible display panel; and
a flexible display panel support apparatus comprising:
a foldable housing comprising a first portion, a second portion, and a third portion, wherein the second portion and the third portion are connected to two opposite sides of the first portion respectively; and
a support mechanism disposed at an internal folding side of the housing and comprising a support assembly and a drive assembly that is connected to the support assembly, an orthographic projection of the support assembly on the housing being located within the first portion, wherein the drive assembly is configured to drive the support assembly to switch to a support state in response to an unfolding motion of the housing or drive the support assembly to switch to a nonsupport state in response to a folding motion of the housing,
wherein the flexible display panel is disposed on a side of the support mechanism away from the housing, the flexible display panel comprises a bent portion, and the support assembly is disposed between the bent portion and the first portion.
